(19) United States
(12) Patent Application Publication
(10) Pub. No.: US 2020/0043953 A1
(43) Pub. Date: Feb. 6, 2020

(54) ARRAY SUBSTRATE AND DISPLAY DEVICE

(71) Applicant: Shenzhen China Star Optoelectronics Technology Co., Ltd., Shenzhen, Guangdong (CN)

(72) Inventors: Mingjue YU, Shenzhen, Guangdong (CN); Yuan Jun HSU, Shenzhen, Guangdong (CN)

(73) Assignee: Shenzhen China Star Optoelectronics Technology Co., Ltd., Shenzhen, Guangdong (CN)

(21) Appl. No.: 15/562,818

(22) PCT Filed: Jun. 27, 2017
(86) PCT No.: PCT/CN2017/090257

§ 371 Date: Aug. 2, 2018

(30) Foreign Application Priority Data
Jun. 5, 2017 (CN) 201710411433.X

(51) Int. Cl. H01L 27/12

(52) U.S. Cl. CPC H01L 27/1225; H01L 27/3262; H01L 27/1255

(57) ABSTRACT

Disclosed are an array substrate and a display device. The array substrate includes a baseplate, a buffer layer and an active layer that are arranged in sequence. The active layer includes a first active region and a second active region. A conducting channel of the first active region is made of a low temperature poly-silicon, and a conducting channel of the second active region is made of an oxide semiconductor. The display device includes the array substrate. Through selecting a low temperature poly-silicon material as a conducting channel material of the first active region and an oxide semiconductor material as a conducting channel material of the second active region, the array substrate and the display device can have a rapid switching speed and a high luminous homogeneity.

### CROSS-REFERENCE TO RELATED APPLICATIONS

This application claims the priority of Chinese patent application CN201710411433.X, entitled “Array substrate and display device” and filed on Jun. 5, 2017, the entirety of which is incorporated herein by reference.

### FIELD OF THE INVENTION

The present disclosure relates to the technical field of display, and in particular, to an array substrate and a display device.

### BACKGROUND OF THE INVENTION

Currently, in the technical field of display, there are mainly two kinds of widely used display devices based on their screen materials, i.e., liquid crystal display (LCD) devices and organic light emitting diode (OLED) display devices. OLEDs have characteristics such as self light-emitting, wide viewing angle, long lifetime, energy conservation and environmental protection. At present, OLED display devices and lighting industry develop in a rapid speed, and OLED display devices have become an important display design. Among the OLED display devices, a display panel of an active matrix organic light emitting diode (AMOLED) comprises pixels that are arranged in an array. Each pixel is driven by a driving circuit constituted by several thin film transistors (TFT) and a storage capacitor. The AMOLED display panel is a kind of active display panel, possesses excellent luminous efficiency, and is usually used in a high-definition and large-size display device. A driving circuit of 2T1C is usually used in an AMOLED. That is, the driving circuit comprises a switching TFT, a driving TFT and a storage capacitor. The switching TFT controls on/off states of the driving TFT through the storage capacitor, and the AMOLED is enabled to be in an operating state by an electric current generated by the driving TFT in a saturation state.

In the current 2T1C driving circuit of the AMOLED, active regions of the switching TFT and the driving TFT are usually made of the same channel material, which is an oxide semiconductor or a low temperature poly-silicon (LTPS) material. When LTPS is used as a channel material of the active region, although the electron mobility of the LTPS material is high, its homogeneity in a large area is not good. When LTPS is used in an active layer of the driving TFT, it may result in inhomogeneity of the electric current, which will adversely affect brightness adjustment of the AMOLED. Meanwhile, the oxide semiconductor material has fine homogeneity and its leakage current is small. Although electron mobility of oxide semiconductor is lower than that of LTPS, it is enough to drive the OLED device.

Therefore, it is necessary to provide an improved array substrate and an improved display device which possess a rapid switching speed and a high luminous homogeneity.

### SUMMARY OF THE INVENTION

With respect to the aforementioned problem in the prior art, the present disclosure provides an array substrate and a display device so as to obtain a rapid switching speed and a high luminous homogeneity.

On the one hand, the present disclosure provides an array substrate, which comprises a baseplate, a buffer layer and an active layer that are arranged in sequence. The active layer includes a first active region and a second active region. A conducting channel of the first active region is made of a low temperature poly-silicon, and a conducting channel of the second active region is made of an oxide semiconductor. According to the present disclosure, through selecting LTPS as a conducting channel material of the first active region and an oxide semiconductor material as a conducting channel material of the second active region, the array substrate can have a rapid switching speed and a high luminous homogeneity.

According to one possible implementation mode of this aspect, the array substrate further comprises a silicon nitride buffer layer deposited between the baseplate and the buffer layer, and the silicon nitride buffer layer is arranged below the first active region. With this arrangement, hydrogenation of the silicon nitride can be used to further improve the electron mobility of the LTPS material and enhance performance of the device.

According to one possible implementation mode of this aspect, the active layer further comprises a bottom plate of a storage capacitor which is made of the low temperature poly-silicon.

According to one possible implementation mode of this aspect, the first active region and the bottom plate of the storage capacitor are obtained from amorphous silicon through a crystallization technology, which is rapid thermal annealing, excimer laser annealing, or solid phase crystallization.

According to one possible implementation mode of this aspect, the first active region further comprises a first source region and a first drain region that are respectively arranged on two sides of the conducting channel of the first active region.

According to one possible implementation mode of this aspect, the first source region, the first drain region and the bottom plate of the storage capacitor are obtained by ion doping.

According to one possible implementation mode of this aspect, an oxide semiconductor material is an indium gallium zinc oxide or an indium tin zinc oxide.

According to one possible implementation mode of this aspect, the array substrate further comprises a first insulating layer, a first metal layer, a second insulating layer, a second metal layer, a protective layer, a flat layer, a transparent electrode layer and a pixel definition layer that are arranged in sequence on the active layer.

On the other hand, the present disclosure provides a display device, which comprises any one of the aforesaid array substrate.

According to of the present disclosure, through selecting the LTPS material as the conducting channel material of the first active region and the oxide semiconductor material as the conducting channel material of the second active region, the array substrate can have the rapid switching speed and the high luminous homogeneity.

The above technical features can be combined in various suitable means or replaced by equivalent technical features as long as the objective of the present disclosure can be achieved.

### BRIEF DESCRIPTION OF THE DRAWINGS

The present disclosure will be described in a more detailed way below based on embodiments and with reference to the accompanying drawings, in the drawings:

FIG. 1 schematically shows a structure of an array substrate according to one embodiment of the present disclosure; and

FIG. 2 schematically shows a structure of an array substrate according to another embodiment of the present disclosure.

In the accompanying drawings, same components use same reference signs. The accompanying drawings are not drawn according to actual proportions.

### DETAILED DESCRIPTION OF THE EMBODIMENTS

The present disclosure will be further illustrated hereinafter with reference to the drawings.

In a driving circuit of an AMOLED, the most widely used one is a 2T1C driving circuit, i.e., the driving circuit comprises a switching TFT element, a driving TFT element and a storage capacitor. According to the present disclosure, the switching TFT element comprises a first active region; the driving TFT element comprises a second active region; and the storage capacitor comprises a top plate and a bottom plate.

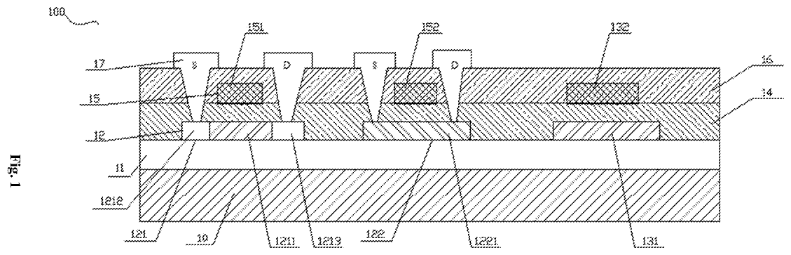

FIG. 1 schematically shows a structure of an array substrate 100 according to the present disclosure. As shown in FIG. 1, the array substrate 100 comprises a baseplate 10 arranged in a bottom layer, and a buffer layer 11 and an active layer 12 that are deposited in sequence on the baseplate 10. The active layer 12 includes a first active region 121, a second active region 122 and a bottom plate 131 of a storage capacitor. A conducting channel 1211 of the first active region 121 and the bottom plate 131 of the storage capacitor are made of a low temperature poly-silicon (LTPS) material, and a conducting channel 1221 of the second active region 122 is made of an oxide semiconductor material.

According to the present disclosure, through selecting the LTPS material as a material of the conducting channel 1211 of the first active region 121 and the oxide semiconductor material as a material of the conducting channel 1221 of the second active region 122, the array substrate 10 can have a rapid switching speed and a high luminous homogeneity.

Specifically, according to the present disclosure, the buffer layer 11, the active layer 12, a first insulating layer 14, a first metal layer 15, a second insulating layer 16, and a second metal layer 17 are arranged in sequence on the array substrate 100. The buffer layer 11 is made of SiO₂ material and is deposited on the baseplate 10. The active layer 12 is deposited on the buffer layer 11 and comprises the first active region 121, the second active region 122, and the bottom plate 131 of the storage capacitor.

The specific procedure of forming the active layer 12 is as follows. An amorphous silicon material is deposited on a corresponding region of the buffer layer 11 for formation of the first active region 121 and the bottom plate 131 of the storage capacitor, and then the oxide semiconductor material is deposited on other region of the buffer layer 11 for formation of the second active region 122. Since an electron mobility of the amorphous silicon material is relatively low, it is not suitable to serve as the conducting channel material. Hence, the amorphous silicon material should be transformed into the low temperature poly-silicon (LTPS) material through a crystallization technology. Preferably, the amorphous silicon material can be transformed into the low temperature poly-silicon (LTPS) material through any one of rapid thermal annealing (RTA), excimer laser annealing (ELA), or solid phase crystallization (SPC).

Preferably, since an electric conductivity of the poly-silicon material is not high, two sides of the first active region 121 and the bottom plate 131 of the storage capacitor can be doped with ions (for example, doped with Ti ions) so as to reduce its resistance and form a first source region 1212 and a first drain region 1213 on the two sides of the first active region 121. Therefore, the first source region 1212 and the first drain region 1213 are connected with each other by the conducting channel 1211. When ions are doped, P type doping or N type doping can be selected.

Preferably, the oxide semiconductor material is an indium gallium zinc oxide (IGZO) or an indium tin zinc oxide (ITZO).

The first insulating layer 14 is deposited on the active layer 12 and is a monolayer of silicon nitride (SiNₓ), a monolayer of silicon dioxide (SiO₂) or a stack-up combination thereof.

Then, the first metal layer 15 is deposited on a corresponding region of the first insulating layer 14 to serve as a gate 151 of the switching TFT element, a gate 152 of the driving TFT element and a top plate 132 of the storage capacitor, respectively. Preferably, the metal layer 15 is made of one selected from a group consisting of molybdenum, aluminium and copper. A top gate TFT structure is adopted in the array substrate 100 of the present disclosure, and parasite capacitor thereof can be effectively reduced.

The second insulating layer 16 and the second metal layer 17 are deposited in sequence on the first metal layer 15. Likewise, the second insulating layer 16 is a monolayer of silicon nitride (SiNₓ), a monolayer of silicon oxide (SiO₂) or a stack-up combination thereof. The second metal layer 17 is made of one selected from a group consisting of molybdenum, aluminium and copper. A plurality of via holes are arranged through the first insulating layer 14 and the second insulating layer 16. A source (S) and a drain (D) of the switching TFT element are connected to the first source region 1212 and the first drain region 1213 through different via holes respectively. A source (S) and a drain (D) of the driving TFT element are connected to the conducting channel 1221 through different via holes respectively.

According to some embodiments, a protective layer, a flat layer, a transparent electrode layer and a pixel definition layer are further arranged in sequence on the second metal layer 17, which are not repeated here.

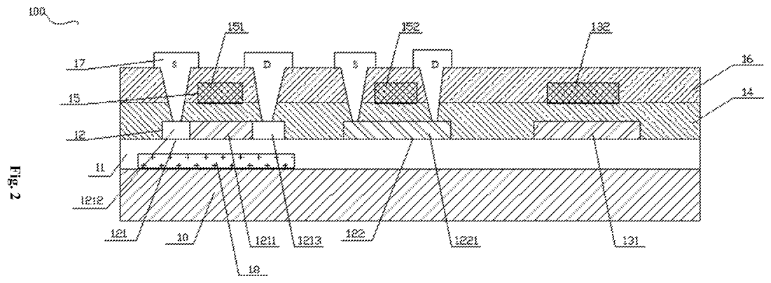

FIG. 2 schematically shows a structure of an array substrate 100 according to another embodiment of the present disclosure. As shown in FIG. 2, a silicon nitride SiNₓ buffer layer 18 is arranged between the baseplate 10 and the buffer layer 11. The silicon nitride buffer layer 18 is located below the first active region 121. Since silicon nitride has a function of self hydrogenation repair, it can further improve the reliability and performance of the device.

The present disclosure further provides a display device, which comprises the array substrate disclosed herein. The display device also has the abovementioned beneficial effects, which will not be repeated here.

According to the present disclosure, through selecting the LTPS material as the conducting channel material of the first active region and the oxide semiconductor material as the conducting channel material of the second active region, the array substrate and the display device can have the rapid switching speed and the high luminous homogeneity.

Although the present disclosure is described hereinabove with reference to specific embodiments, it can be understood that, these embodiments are merely examples of the principles and applications of the present disclosure. Hence, it can be understood that, numerous modifications can be made to the embodiments, and other arrangements can be made, as long as they do not go beyond the spirit and scope of the present disclosure as defined by the appended claims. It can be understood that, different dependent claims and features described herein can be combined in a manner different from those described in the initial claims. It can also be understood that, the technical features described in one embodiment can also be used in other embodiments.

1. An array substrate, comprising a baseplate, a buffer layer and an active layer that are arranged in sequence,
wherein the active layer includes a first active region and a second active region; and
wherein a conducting channel of the first active region is made of a low temperature poly-silicon, and a conducting channel of the second active region is made of an oxide semiconductor.

2. The array substrate according to claim 1, further comprising a silicon nitride buffer layer deposited between the baseplate and the buffer layer, wherein the silicon nitride buffer layer is arranged below the first active region.

3. The array substrate according to claim 1, wherein the active layer further comprises a bottom plate of a storage capacitor which is made of the low temperature poly-silicon.

4. The array substrate according to claim 2, wherein the active layer further comprises a bottom plate of a storage capacitor which is made of the low temperature poly-silicon.

5. The array substrate according to claim 4, wherein the first active region and the bottom plate of the storage capacitor are obtained from amorphous silicon through a crystallization technology, which is rapid thermal annealing, excimer laser annealing, or solid phase crystallization.

6. The array substrate according to claim 5, wherein the first active region further comprises a first source region and a first drain region that are respectively arranged on two sides of the conducting channel of the first active region.

7. The array substrate according to claim 6, wherein the first source region, the first drain region and the bottom plate of the storage capacitor are obtained by ion doping.

8. The array substrate according to claim 7, wherein the oxide semiconductor is an indium gallium zinc oxide or an indium tin zinc oxide.

9. The array substrate according to claim 8, further comprising a first insulating layer, a first metal layer, a second insulating layer, a second metal layer, a protective layer, a flat layer, a transparent electrode layer and a pixel definition layer that are arranged in sequence on the active layer.

10. A display device, comprising an array substrate, which comprises a baseplate, a buffer layer and an active layer that are arranged in sequence,
wherein the active layer includes a first active region and a second active region; and
wherein a conducting channel of the first active region is made of a low temperature poly-silicon, and a conducting channel of the second active region is made of an oxide semiconductor.

11. The display device according to claim 10, wherein the array substrate further comprises a silicon nitride buffer layer deposited between the baseplate and the buffer layer, and the silicon nitride buffer layer is arranged below the first active region.

12. The display device according to claim 10, wherein the active layer further comprises a bottom plate of a storage capacitor which is made of the low temperature poly-silicon.

13. The display device according to claim 11, wherein the active layer further comprises a bottom plate of a storage capacitor which is made of the low temperature poly-silicon.

14. The display device according to claim 13, wherein the first active region and the bottom plate of the storage capacitor are obtained from amorphous silicon through a crystallization technology, which is rapid thermal annealing, excimer laser annealing, or solid phase crystallization.

15. The display device according to claim 14, wherein the first active region further comprises a first source region and a first drain region that are respectively arranged on two sides of the conducting channel of the first active region.

16. The display device according to claim 15, wherein the first source region, the first drain region and the bottom plate of the storage capacitor are obtained by ion doping.

17. The display device according to claim 16, wherein the oxide semiconductor is an indium gallium zinc oxide or an indium tin zinc oxide.

18. The display device according to claim 17, wherein the array substrate further comprises a first insulating layer, a first metal layer, a second insulating layer, a second metal layer, a protective layer, a flat layer, a transparent electrode layer and a pixel definition layer that are arranged in sequence on the active layer.
